(19) United States
(12) Patent Application Publication
(10) Pub. No.: US 2012/0039489 A1
(43) Pub. Date: Feb. 16, 2012

(54) VOLUME CONTROL METHOD AND ELECTRONIC DEVICE CAPABLE OF AUTOMATIC VOLUME ADJUSTMENT

(76) Inventors: YI-CHIUNG CHEN, New Taipei City (TW); Po-Hsu Chen, New Taipei City (TW)

(21) Appl. No.: 13/205,825

(22) Filed: Aug. 9, 2011

(30) Foreign Application Priority Data
Aug. 11, 2010 (TW) 099126745
Jul. 8, 2011 (TW) 100124239

(51) Int. Cl. H03G 3/00

(52) U.S. Cl. 381/107

(57) ABSTRACT

A volume control method is to be performed by an electronic device for adjusting intensity of an output audio signal outputted from the electronic device according to an external audio signal of an environment in which the electronic device is located. The volume control method includes: configuring the electronic device to receive the external audio signal; configuring the electronic device to compare a sound track of the external audio signal with a preset sound track and to make a determination as to whether a degree of similarity between the two sound tracks reaches a preset ratio; and configuring the electronic device to stop outputting the output audio signal when a result of the determination is affirmative.

### CROSS-REFERENCE TO RELATED APPLICATION

This application claims priority of Taiwanese Applications No. 099126745, filed on Aug. 11, 2010 and No. 100124239, filed on Jul. 8, 2011.

### BACKGROUND OF THE INVENTION

1. Field of the Invention

The present invention relates to a control method, more particularly to a volume control method for adjusting volume of an electronic device.

2. Description of the Related Art

A television is currently an essential home appliance in modern life. However, when people are watching television, they often find that volume of the television is too loud or too small resulting from surrounding environment factors, for example: a mobile phone ringtone, such that they have to adjust the volume of the television manually. Nevertheless, they may miss important program content when adjusting the volume of the television.

Therefore, in order to overcome the aforementioned issue, a conventional volume adjustment technology may configure a television to automatically adjust volume of sound outputted thereby according to sound of its surrounding environment. However, according to the conventional volume adjustment technology, once the sound is determined as not outputted from the television, the sound is presumed to be noise from surrounding environment. Accordingly, when a user's mobile phone rings, the television may be configured to falsely determine the mobile phone ringtone to be noise and increase the volume of sound outputted thereby, such that the user has to manually decrease the volume of the television and that the user is disturbed from watching television. Furthermore, the conventional volume adjustment technology blindly configures the television to increase the volume of the television so as to mask noise from surrounding environment. Therefore, when audio signal in the surrounding environment is too strong, the television outputs higher sound volume correspondingly such that hearing of the user is damaged unconsciously.

### SUMMARY OF THE INVENTION

Therefore, an object of the present invention is to provide a volume control method capable of adjusting volume of an electronic device according to an external audio signal of an environment in which the electronic device is located.

Accordingly, the volume control method of the invention is to be performed by an electronic device for adjusting intensity of an output audio signal outputted from the electronic device according to an external audio signal of an environment in which the electronic device is located. The volume control method comprises:

(A) configuring the electronic device to receive the external audio signal;

(B) configuring the electronic device to compare a sound track of the external audio signal with a preset sound track and to make a first determination as to whether a degree of similarity between the two sound tracks reaches a preset ratio, the preset sound track being preferably a sound track of a ringtone of a user's mobile phone so as to determine whether the external audio signal of the environment in which the electronic device is located is the ringtone of the user's mobile phone; and

(C) configuring the electronic device to stop outputting the output audio signal when a result of the first determination is affirmative, i.e., the external audio signal is the ringtone of the user's mobile phone.

Preferably, the volume control method further comprises:

(D) configuring the electronic device to receive the external audio signal during a pause time of the output audio signal outputted from the electronic device when the result of the first determination is negative, i.e., the external audio signal is noise; and

(E) configuring the electronic device to adjust the intensity of the output audio signal according to the external audio signal received during the pause time such that the intensity of the output audio signal is higher than intensity of the external audio signal.

Moreover, the volume control method further comprises step (F) to be performed after step (C):

(F) configuring the electronic device to make a second determination as to whether a mute canceling command is received,

wherein step (A) is performed and the electronic device proceeds to output the output audio signal when a result of the second determination is affirmative, and

wherein step (C) is performed when the result of the second determination is negative.

Preferably, step (E) includes:

(E.1) configuring the electronic device to set a target intensity of the output audio signal higher than the intensity of the external audio signal with reference to an audio intensity look-up table;

(E.2) configuring the electronic device to adjust the intensity of the output audio signal according to the target intensity thereof; and

(E.3) configuring the electronic device to make a third determination as to whether the intensity of the output audio signal has reached the target intensity thereof, wherein steps (E.2) and (E.3) are repeated until a result of the third determination is affirmative.

Preferably, the volume control method further comprises steps (G) and (H) to be performed before step (A):

(G) configuring the electronic device to receive the external audio signal; and

(H) configuring the electronic device to adjust the intensity of the output audio signal according to the received external audio signal such that the intensity of the output audio signal is higher than intensity of the external audio signal.

Further, step (H) includes:

(H.1) configuring the electronic device to set a target intensity of the output audio signal higher than the intensity of the external audio signal with reference to an audio intensity look-up table;

(H.2) configuring the electronic device to adjust the intensity of the output audio signal according to the target intensity thereof; and

(H.3) configuring the electronic device to make a fourth determination as to whether the intensity of the output audio signal has reached the target intensity thereof, wherein step (A) is performed when a result of the fourth determination is affirmative, and wherein steps (H.2) and (H.3) are repeated when the result of the fourth determination is negative.

Another object of the present invention is to provide an electronic device capable of automatic volume adjustment and capable of performing the aforementioned volume control method.

Accordingly, the electronic device capable of automatic volume adjustment of the invention, comprises a memory unit, an audio output unit, an audio receiver unit, a control unit and a sound track comparison unit.

The memory unit is for storing a preset sound track. The audio output unit is for outputting an output audio signal. The audio receiver unit is for receiving an external audio signal of an environment in which the electronic device is located. The control unit is coupled to the memory unit, the audio output unit and the audio receiver unit. The soundtrack comparison unit is coupled to the control unit. The sound track comparison unit compares a sound track of the external audio signal with the preset sound track so as to determine whether a degree of similarity between the two sound tracks reaches a preset ratio. The control unit is configured to control the audio output unit to stop outputting the output audio signal when a result of determination made by the sound track comparison unit is affirmative.

An effect of the invention resides in that the electronic device is configured to receive the external audio signal of the environment in which the electronic device is located, to determine whether the external audio signal is a noise or a preset ringtone of a user's mobile phone, and to perform volume control correspondingly, so as to facilitate convenience in use.

### BRIEF DESCRIPTION OF THE DRAWINGS

Other features and advantages of the present invention will become apparent in the following detailed description of the preferred embodiment with reference to the accompanying drawings, of which:

FIG. 1 is a flow chart illustrating a preferred embodiment of the volume control method according to an embodiment of the invention, in which processing procedures of an initial mode are shown in this flow chart;

FIG. 2 is a flow chart illustrating the preferred embodiment of the volume control method according to an embodiment of the invention, in which processing procedures of a working mode are shown in this flowchart;

FIG. 3 is a block diagram of an electronic device for performing the preferred embodiment of the volume control method; and

FIG. 4 is an audio intensity look-up table illustrating a relation between intensity of an external audio signal and intensity of an output audio signal outputted from the electronic device.

### DETAILED DESCRIPTION OF THE PREFERRED EMBODIMENT

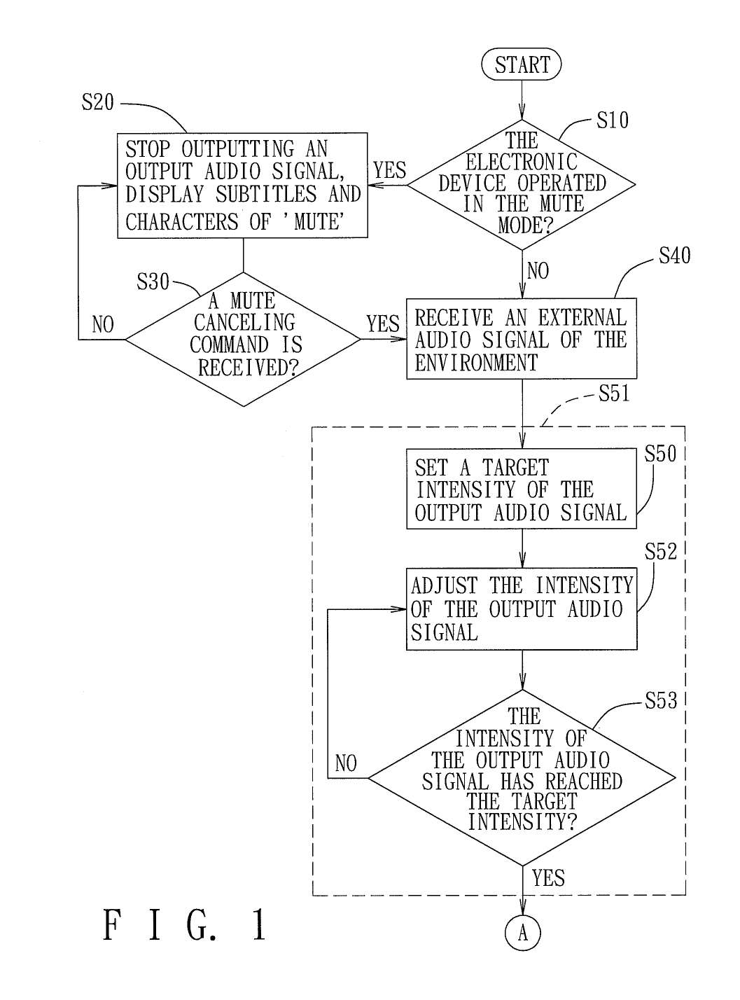

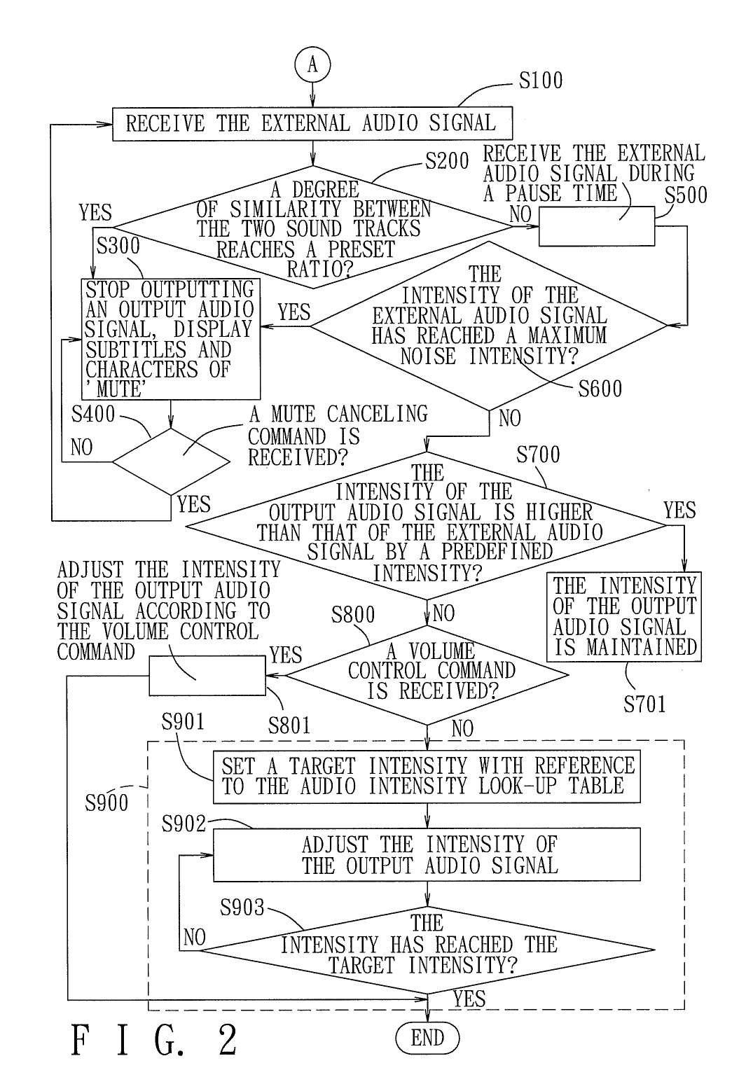

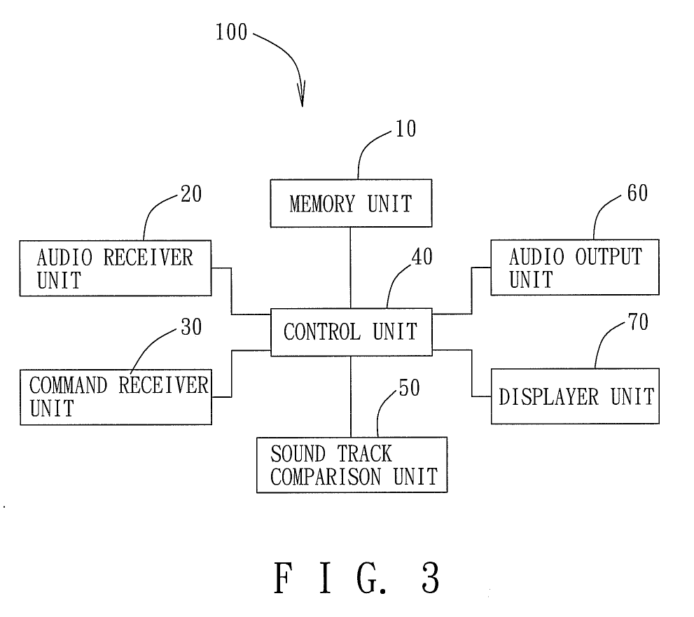

Referring to FIG. 1 and FIG. 2, a preferred embodiment of a volume control method according to an embodiment of the invention is illustrated. The volume control method is to be performed by an electronic device 100 (as illustrated in FIG. 3) for causing the electronic device 100 to adjust volume of sound outputted thereby, such that when external sound of an environment in which the electronic device 100 is located varies (for example, from a noisier daytime to a quieter nighttime), the electronic device 100 is capable of varying the volume of sound outputted thereby automatically such that users may listen to the sound with appropriate volume. In this embodiment, a television is given as an example of the electronic device 100, but the electronic device 100 should not be limited thereto.

Referring to FIG. 3, the electronic device 100 comprises a memory unit 10, an audio receiver unit 20, a command receiver unit 30, a control unit 40, a sound track comparison unit 50, an audio output unit 60 and a displayer unit 70.

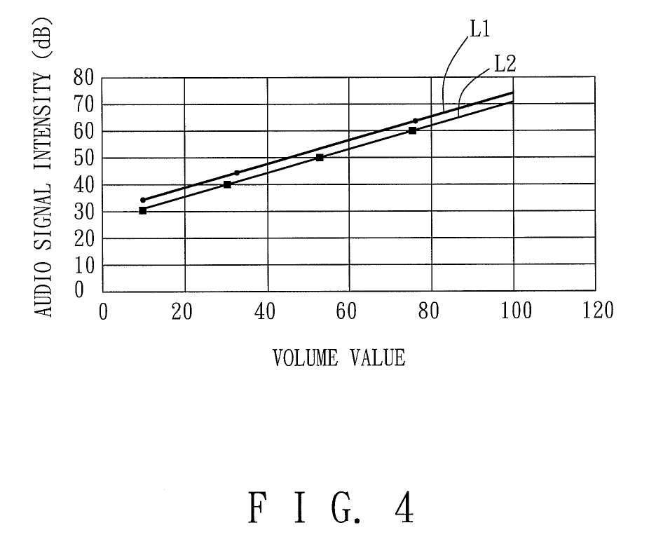

The memory unit 10 is for storing a preset soundtrack, and an audio intensity look-up table such as that shown in FIG. 4. In this embodiment, the preset sound track is a sound track of a mobile phone ringtone stored by a user in advance. The audio receiver unit 20 is a microphone for receiving an external audio signal of an environment in which the electronic device 100 is located. The command receiver unit 30 is for receiving a control command sent from peripheral equipment (not shown), such as a remote controller, operated by the user, for example, activate/cancel mute. The sound track comparison unit 50 is for comparing a sound track of the external audio signal received at the audio receiver unit 20 with the preset sound track stored in the memory unit 10. The audio output unit 60 includes a speaker which is for outputting an output audio signal and is composed of other electronic components such as an audio decoder and a digital-to-analog converter (DAC). Since the feature of the invention does not reside in the detailed configuration of the audio output unit 60, further details of the same are omitted herein for the sake of brevity. The displayer unit 70 is a liquid crystal displayer. The control unit 40 is coupled to the memory unit 10, the audio receiver unit 20, the command receiver unit 30, the sound track comparison unit 50, the audio output unit 60 and the displayer unit 70 for controlling operation of each component.

The following description explains how the electronic device 100 controls volume of sound outputted thereby according to external sound. Specifically, the electronic device 100 of the invention is operable in an initial mode (FIG. 1) in which the electronic device 100 is just turned on, a mute mode in which no sound is outputted, and a working mode (FIG. 2).

Referring to step S10 in FIG. 1, the electronic device 100 is configured to operate in the initial mode when just turned on, and the control unit 40 is configured to make a first determination, with reference to a volume parameter recorded before the electronic device 100 was turned off, as to whether the electronic device 100 was configured to operate in the mute mode at the time the electronic device 100 was turned off. The control unit 40 is configured to stay in the mute mode (i.e., steps S20 and S30 are performed) when a result of the first determination is affirmative. Otherwise, step 40 is performed when the result of the first determination is negative.

In this embodiment, operation of the electronic device 100 in the mute mode is illustrated in steps S20 and S30. In step S20, the control unit 40 is configured to control the audio output unit 60 to stop outputting the output audio signal, and simultaneously control the displayer unit 70 to display subtitles corresponding to current output images and characters of ‘mute’.

In step 30, the control unit 40 is configured to make a second determination as to whether the command receiver unit 30 has received a mute canceling command. Step S40 is performed when a result of the second determination is affirmative. Otherwise, steps S20 and S30 are repeated when the result of the second determination is negative. In this embodiment, when the command receiver unit 30 has received the mute cancelling command transmitted as a result of operation of the remote controller or pushing of a mute button (not shown) of the electronic device 100 by the user, the command receiver unit 30 is configured to send a control signal to the control unit 40 such that the control unit 40 is configured to in turn detect the external audio signal of the environment according to the control signal.

Specifically, in this embodiment, if the electronic device 100 had been operated in the mute mode at the time the electronic device 100 was turned off, the electronic device 100 is still configured to stay in the mute mode (step S20) until the user cancels mute operation manually (step S30) when the electronic device 100 is turned on anew. In other configurations of the invention, steps S10 to S30 are omitted and the control unit 40 is configured to perform step S40 directly when the electronic device 100 is turned on, regardless of whether the electronic device 100 had been configured to operate in the mute mode or not before being turned off.

In step S40, the control unit 40 is configured to control the audio receiver unit 20 to receive the external audio signal of the environment in which the electronic device 100 is located, and to perform step S50 thereafter. In step S50, the control unit 40 is configured to adjust intensity of the output audio signal outputted at the audio output unit 60 with reference to the audio intensity look-up table (see FIG. 4) stored in the memory unit 10.

Referring to FIG. 4, an abscissa of the audio intensity look-up table represents volume values associated with the intensity of the output audio signal. The volume values correspond to a volume bar (usually from 0 to 100) displayed on the displayer unit 70. An ordinate of the audio intensity look-up table represents audio signal intensity measured in Decibel (dB). A curve L1 of the audio intensity look-up table is a curve representing the intensity of the output audio signal which shall be outputted at the audio output unit 60. A curve L2 of the audio intensity look-up table is a curve representing intensity of the external audio signal received at the audio receiver unit 20. In this embodiment, for ensuring that the user may still listen to the sound outputted from the electronic device 100 in a noisy environment, the intensity of the output audio signal outputted at the audio output unit 60 is required to be higher than the intensity of the external audio signal by a predefined intensity (in this embodiment, 3 dB). In other words, the curve L1 is the curve L2 shifted 3 dB upwardly. For example, when the intensity of the external audio signal is 70 dB, the intensity of the output audio signal outputted at the audio output unit 60 is 73 dB and the volume value corresponding to the volume bar displayed on the displayer unit 70 is 98.

Furthermore, step S50 includes the following sub-steps:

In step S51, the control unit 40 is configured to set a target intensity of the output audio signal which is 3 dB higher than the intensity of the external audio signal with reference to an audio intensity look-up table. For example, if the intensity of the external audio signal is 60 dB, the target intensity is 63 dB.

In step S52, the control unit 40 is configured to adjust the intensity of the output audio signal outputted at the audio output unit 60 according to the target intensity thereof. Specifically, the intensity of the output audio signal outputted at the audio output unit 60 is increased from an initial intensity, and the displayer unit 70 is simultaneously configured to display the volume bar which has a length gradually increasing with rise of the intensity of the output audio signal. In this embodiment, the initial intensity is 30 dB and the volume value corresponding to the volume bar displayed on the displayer unit 70 is 10, such that the audio output unit 60 may be prevented from outputting excessive volume and reducing service life thereof when the electronic device 100 is just turned on.

In step S53, the control unit 40 is configured to make a third determination as to whether the intensity of the output audio signal outputted at the audio output unit 60 has reached the target intensity (63 dB) thereof. The audio output unit 60 is configured to maintain the intensity of the output audio signal at 63 dB and operate in the working mode when a result of the third determination is affirmative. Otherwise, steps S52 and S53 are repeated until the intensity of the output audio signal reaches the target intensity (63 dB) thereof when the result of the third determination is negative.

In summary, when the electronic device 100 is turned on, the audio output unit 60 is configured to gradually increase the intensity of the output audio signal from the initial intensity thereof (the volume value corresponding to the volume bar is 10) as long as the electronic device 100 had not been operated in the mute mode at the time the electronic device 100 was turned off. In this embodiment, the intensity of the output audio signal is increased at speed of 1 volume value corresponding to the volume bar per 500 ms until the intensity of the output audio signal reaches the target intensity thereof set by the control unit 40. That is, when the electronic device 100 is turned on, steps S10 to S50 are performed first so as to adjust the intensity of the output audio signal from the initial intensity to the target intensity suitable for the surrounding environment, such that damage to the audio output unit 60 resulting from outputting excessive volume may be prevented when the electronic device 100 is just turned on.

Referring to FIG. 2, in the working mode, step S100 is performed by the control unit 40. In step S100, the control unit 40 is configured to control the audio receiver unit 20 to receive the external audio signal. Notably, the control unit 40 is configured to periodically (for example, at one-minute intervals) control the audio receiver unit 20 to receive the external audio signal, and each duration of receiving the external audio signal lasts 30 seconds. However, the actual configurations are not limited to the disclosure of this embodiment.

Subsequently, step S200 is performed. In step S200, the sound track comparison unit 50 is configured to compare the sound track of the external audio signal with the preset sound track (i.e., the sound track of the mobile phone ringtone) stored in the memory unit 10 and to make a fourth determination as to whether a degree of similarity between the two soundtracks reaches a preset ratio (in this embodiment, 70% is given as an example of the preset ratio). The received external audio signal is deemed to be the mobile phone ring tone when a result of the fourth determination is affirmative. Accordingly, the control unit 40 is configured to perform step S300 and operate in the mute mode. In step S300, the control unit 40 is configured to disable the audio output unit 60 from outputting the output audio signal temporarily, to control the displayer unit 70 to display the subtitles corresponding to the current output images and the characters of ‘mute’ so as to prevent the user from experiencing interference resulting from sound emitted by the electronic device 100 when answering the phone, and to perform step S400 thereafter. Specifically, the sound track comparison unit 50 is configured to compare whether each byte of the sound track of the external audio signal is the same as a respective byte of the preset sound track, and to determine that the external audio signal is the mobile phone ringtone when a number of the same bytes occupies a total number of the bytes by the preset ratio (70%). It is noted that there are other ways to compare sound tracks, and the invention is not limited to the disclosure of the preferred embodiment. On the contrary, step S500 is performed when the degree of similarity between the two sound tracks does not reach the preset ratio.

That is, since the external audio signal received at the audio receiver unit 20 may include the user's mobile phone ring tone and external noise, in step S200, the external audio signal is determined to be noise when the sound track comparison unit 50 determines that the degree of similarity between the sound track of the external audio signal and the preset sound track of the mobile phone is low (i.e., lower than 70%).

In step S400, the control unit 40 is configured to make a fifth determination as to whether the command receiver unit 30 has received the mute cancelling command transmitted as a result of operation of the remote controller or pushing of the mute button of the electronic device 100 by the user. Step S100 is performed when a result of the fifth determination is affirmative. Otherwise, steps S300 and S400 are repeated when the result of the fifth determination is negative.

In step S500, the control unit 40 is configured to control the audio receiver unit 20 to receive the external audio signal during a pause time of the output audio signal outputted at the audio output unit 60. The pause time mentioned herein is a break without any sound between sounds emitted from the television. During the pause time, the external audio signal received at the audio receiver unit 20 does not contain the output audio signal. That is, only sound other than that from the electronic device 100 is included in the external audio signal, such that the control unit 40 may determine intensity of the noise more precisely.

Therefore, step S600 is performed after the audio receiver unit 20 has received the external audio signal. In step S600, the control unit 40 is configured to make a sixth determination as to whether the intensity of the external audio signal received at the audio receiver unit 20 has reached a maximum noise intensity, i.e., determining whether decibel of the intensity of the external audio signal is equal to decibel of the maximum noise intensity (for example, 73 dB). When a result of the sixth determination is affirmative, the noise of the environment in which the electronic device 100 is located has reached a maximum value of the audio intensity look-up table, and the audio output unit 60 may no longer output the output audio signal which has an intensity 3 dB higher than the intensity of the external audio signal. That is, referring to FIG. 4, when the intensity of the external audio signal has reached the maximum noise intensity (for example, 73 dB), the volume value corresponding to the volume bar of the electronic device 100 has reached 100 and may not be increased anymore. At this moment, for protecting the hearing of the user from damage resulting from excessive volume, the control unit 40 is configured to perform steps S300 and S400 and operate in the mute mode, so as to reduce overall environment volume and protect the hearing of the user simultaneously. Back to step S600, step S700 is performed when the result of the sixth determination is negative.

In step S700, the control unit 40 is configured to make a seventh determination, according to the intensity (dB) of the audio signal outputted at the audio output unit 60, as to whether the intensity of the output audio signal is higher than the intensity of the external audio signal by a predefined intensity, for example, 3 dB. This means that the noise of the environment where the user is at may not interfere with the user watching television when a result of the seventh determination is affirmative. Therefore, step S701 is performed. In step S701, the intensity of the output audio signal outputted at the audio output unit 60 maintained. Otherwise, step S800 is performed when the result of the seventh determination is negative.

In step S800, the control unit 40 is configured to make an eighth determination as to whether the command receiver unit 30 has received a volume control command from the remote controller. When a result of the eighth determination is affirmative, this means that the user desires to adjust volume of the electronic device 100 manually, and step 801 is thus performed. In step 801, the control unit 40 is configured to adjust the intensity of the output audio signal outputted at the audio output unit 60 according to the volume control command, i.e., the intensity of the output audio signal is adjusted as desired by the user, and the flow ends. Back to step S800, step S900 is performed when the result of the eighth determination is negative. In step S900, the control unit 40 is configured to adjust the intensity of the output audio signal outputted at the audio output unit 60 with reference to the audio intensity look-up table (referring to FIG. 4) stored in the memory unit 10.

Furthermore, step S900 includes the following sub-steps:

In step S901, the control unit 40 is configured to set a target intensity of the output audio signal higher than the intensity of the external audio signal by, for example 3 dB, with reference to the audio intensity look-up table stored in the memory unit 10.

In step S902, the control unit 40 is configured to adjust the intensity of the output audio signal according to the target intensity thereof. Specifically, step S902 in the working mode is different from step S52 in the initial mode. In the initial mode, the control unit 40 is configured to control the intensity of the output audio signal outputted at the audio output unit 60 to increase from the initial intensity. However, in the working mode, the control unit 40 is configured to control the intensity of the output audio signal outputted at the audio output unit 60 from a current intensity to the target intensity. That is, the intensity of the output audio signal outputted at the audio output unit 60 may be increased or decreased.

In step S903, the control unit 40 is configured to make a ninth determination as to whether the intensity (dB) of the output audio signal outputted at the audio output unit 60 has reached the target intensity (dB) thereof. When a result of the ninth determination is affirmative, the control unit 40 is configured to maintain the intensity of the output audio signal, to end the process flow, and to wait for next detection of the external audio signal of the environment. Otherwise, steps S902 and S903 are repeated when the result of the ninth determination is negative.

In summary, by means of the volume control method of the invention, the electronic device 100 is capable of automatically adjusting the intensity of the output audio signal outputted thereby according to the intensity of the noise (the external audio signal) of the environment in which the electronic device 100 is located. Therefore, the user is not required to manually adjust volume of the electronic device 100 resulting from variation in noise of the surrounding environment, so as to facilitate convenience in use. Moreover, the volume control method of the invention is further configured to control the electronic device 100 to operate in the mute mode automatically when the user's mobile phone is ringing, such that the user is prevented from experiencing interference of the sound emitted from the electronic device 100 when answering the phone.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A volume control method to be performed by an electronic device for adjusting intensity of an output audio signal outputted from the electronic device according to an external audio signal of an environment in which the electronic device is located, the volume control method comprising:
(A) configuring the electronic device to receive the external audio signal;
(B) configuring the electronic device to compare a sound track of the external audio signal with a preset sound track and to make a first determination as to whether a degree of similarity between the two sound tracks reaches a preset ratio; and
(C) configuring the electronic device to stop outputting the output audio signal when a result of the first determination is affirmative.

2. The volume control method as claimed in claim 1, further comprising:
(D) configuring the electronic device to receive the external audio signal during a pause time of the output audio signal outputted from the electronic device when the result of the first determination is negative; and
(E) configuring the electronic device to adjust the intensity of the output audio signal according to the external audio signal received during the pause time such that the intensity of the output audio signal is higher than intensity of the external audio signal.

3. The volume control method as claimed in claim 1, further comprising step (F) to be performed after step (C):
(F) configuring the electronic device to make a second determination as to whether a mute canceling command is received,
wherein step (A) is performed and the electronic device proceeds to output the output audio signal when a result of the second determination is affirmative, and
wherein step (C) is performed when the result of the second determination is negative.

4. The volume control method as claimed in claim 2, wherein step (E) includes:
(E.1) configuring the electronic device to set a target intensity of the output audio signal higher than the intensity of the external audio signal with reference to an audio intensity look-up table;
(E.2) configuring the electronic device to adjust the intensity of the output audio signal according to the target intensity thereof; and
(E.3) configuring the electronic device to make a third determination as to whether the intensity of the output audio signal has reached the target intensity thereof, wherein steps (E.2) and (E.3) are repeated until a result of the third determination is affirmative.

5. The volume control method as claimed in claim 1, further comprising steps (G) and (H) to be performed before step (A):
(G) configuring the electronic device to receive the external audio signal; and
(H) configuring the electronic device to adjust the intensity of the output audio signal according to the received external audio signal such that the intensity of the output audio signal is higher than intensity of the external audio signal.

6. The volume control method as claimed in claim 5, wherein step (H) includes:
(H.1) configuring the electronic device to set a target intensity of the output audio signal higher than the intensity of the external audio signal with reference to an audio intensity look-up table;
(H.2) configuring the electronic device to adjust the intensity of the output audio signal according to the target intensity thereof; and
(H.3) configuring the electronic device to make a fourth determination as to whether the intensity of the output audio signal has reached the target intensity thereof, wherein step (A) is performed when a result of the fourth determination is affirmative, and wherein steps (H.2) and (H.3) are repeated when the result of the fourth determination is negative.

7. The volume control method as claimed in claim 2, further comprising step (I) between step (D) and step (E):
(I) configuring the electronic device to make a fifth determination as to whether the intensity of the external audio signal has reached a maximum noise intensity, wherein the electronic device is configured to stop outputting the output audio signal when a result of the fifth determination is affirmative, and wherein step (E) is performed when the result of the fifth determination is negative.

8. The volume control method as claimed in claim 7, further comprising step (J) between step (I) and step (E):
(J) configuring the electronic device to make a sixth determination as to whether the intensity of the output audio signal is higher than the intensity of the external audio signal by a predefined intensity, wherein the intensity of the output audio signal is kept the same when a result of the sixth determination is affirmative, and wherein step (E) is performed when the result of the sixth determination is negative.

9. The volume control method as claimed in claim 1, wherein, in step (A), the electronic device is configured to receive the external audio signal periodically.

10. An electronic device capable of automatic volume adjustment, comprising:
a memory unit for storing a preset sound track;
an audio output unit for outputting an output audio signal;
an audio receiver unit for receiving an external audio signal of an environment in which said electronic device is located;
a control unit coupled to said memory unit, said audio output unit and said audio receiver unit; and
a sound track comparison unit coupled to said control unit, said sound track comparison unit comparing a sound track of the external audio signal with the preset sound track so as to determine whether a degree of similarity between the two sound tracks reaches a preset ratio;
wherein said control unit is configured to control said audio output unit to stop outputting said output audio signal when a result of determination made by said sound track comparison unit is affirmative.

11. The electronic device capable of automatic volume adjustment as claimed in claim 10, wherein, when the result of the determination made by said sound track comparison unit is negative, said control unit is configured to control said audio receiver unit to receive the external audio signal during a pause time of said output audio signal, and adjusts intensity of said output audio signal according to the external audio signal received during the pause time such that the intensity of said output audio signal is higher than intensity of the external audio signal.

12. The electronic device capable of automatic volume adjustment as claimed in claim 10, wherein said memory unit further stores an audio intensity look-up table which is related to the intensity of said output audio signal outputted from said audio output unit, wherein, when the result of the determination made by said sound track comparison unit is negative, said control unit is configured to set a target intensity of said output audio signal higher than intensity of the external audio signal with reference to said audio intensity look-up table, and to adjust the intensity of said output audio signal according to the target intensity thereof until the intensity of said output audio signal reaches the target intensity thereof.
